(19) United States
(12) Patent Application Publication
(10) Pub. No.: US 2004/0065933 A1
(43) Pub. Date: Apr. 8, 2004

(54) Flip chip optical and imaging sensor device

(76) Inventors: Chee Seng Foong, Selangor (MY); Kok Wai Mui, Petaling Jaya (MY); Lan Chu Tan, Selangor (MY)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/267,348

(22) Filed: Oct. 8, 2002

(51) Int. Cl. H01L 31/0203

(52) U.S. Cl. 257/433

(57) ABSTRACT

An image sensor device (10) has a transparent base carrier (12) and a circuit substrate (18) having a first side (20) attached to one planar side (14) of the base carrier (12). The substrate (18) includes a peripheral area (24) and a window area (26) that allows radiation to pass therethrough. A sensor integrated circuit (40) having an active area and a peripheral bonding pad area is connected to a second side (22) of the substrate (18) via flip chip bumps (42). Solder balls (46) are attached to an outer peripheral area of the second side (22) of the substrate (18). The substrate (18) provides for electrical interconnect between the solder balls (46) and the flip chip bumps (42). The overall device has a thickness of less than about 1.0 mm.

### BACKGROUND OF THE INVENTION

The present invention relates generally to the packaging of electrical components, and more particularly, to a method of packaging an imaging sensing circuit.

There has been a constant demand for smaller and smarter industrial and consumer electronic products such as digital cameras, camcorders, audio players, etc. Such miniaturization and increased functionality has benefited from advances in the design and manufacturing of semiconductor circuits and wafers. There has also been a marked increase in the use of optical and image sensors in electronic products. At present, all of the available optical and image sensors are packaged in conventional, rigid base carriers such as ceramics or organic substrates. Rigid organic substrates are generally made from BT (bismaleimide-triazine) resin, or FR-4. All of these packages are wire bonded, and such packages are relatively large and thick. Thus, although the package size of image sensors has decreased, there is still room for improvement, as smaller package footprint and height are critical in assuring that more intelligence and functionality may be incorporated into new electronic devices.

### BRIEF DESCRIPTION OF THE DRAWINGS

The foregoing summary, as well as the following detailed description of the present invention, will be better understood when read in conjunction with the appended drawings. For the purpose of illustrating the invention, there is shown in the drawings an embodiment that is presently preferred. It should be understood, however, that the invention is not limited to the precise arrangement and instrumentalities shown. In the drawings:

FIG. 1 is an enlarged, exploded side view of an optical sensor device in accordance with the present invention;

FIG. 2 is an enlarged perspective view of a base carrier and substrate prior to being attached of the sensor device of FIG. 1;

FIG. 3 is an enlarged top view of an array of substrates; and

FIGS. 4-7 are enlarged cross-sectional views illustrating the steps of forming the sensor device of FIG. 1.

### DETAILED DESCRIPTION OF PREFERRED EMBODIMENTS

The detailed description set forth below in connection with the appended drawings is intended as a description of the presently preferred embodiment of the invention, and is not intended to represent the only form in which the present invention may be practiced. It is to be understood that the same or equivalent functions may be accomplished by different embodiments that are intended to be encompassed within the spirit and scope of the invention.

Certain features in the drawings have been enlarged for ease of illustration and the drawings and the elements thereof are not necessarily in proper proportion. However, those of ordinary skill in the art will readily understand such details. In the drawings, like numerals are used to indicate like elements throughout.

The present invention provides a flip chip image sensor packaged in a very thin medium, resulting in a very thin sensor. In a first embodiment of the invention, an image sensor device comprises a transparent base carrier having first and second opposing planar sides and a circuit substrate having first and second opposing sides. The first side of the circuit substrate is attached to the first planar surface of the base carrier. The circuit substrate further includes a substrate peripheral area and a central window area that allows radiation to pass from the base carrier through the window area. A sensor integrated circuit having an active area and a peripheral bonding pad area, the peripheral bonding pad area including bonding pads, overlies the circuit substrate and the bonding pads are electrically connected to the second side of the circuit substrate via flip chip bumps. Solder balls are attached to the substrate peripheral area of the second side of the circuit substrate. The circuit substrate provides electrical interconnect between the solder balls and the flip chip bumps.

The present invention further provides a method of making an image sensor device, including the steps of:

providing a transparent base carrier having first and second opposing planar surfaces;

attaching a first side of a circuit substrate to the first planar surface of the transparent base carrier, wherein the circuit substrate includes a peripheral area and a central window area that allows radiation to pass therethrough;

connecting a sensor integrated circuit to an inner portion of the peripheral area on a second side of the circuit substrate, wherein the sensor integrated circuit has an active area and a peripheral bonding pad area having bonding, wherein the bonding pads are electrically connected to the inner portion of the peripheral area of the circuit substrate via flip chip bumps; and

attaching solder balls to an outer portion of the peripheral area of the second side of the circuit substrate, wherein the circuit substrate provides for electrical interconnect between the solder balls and the flip chip bumps.

Referring now to FIG. 1, an enlarged, exploded side view of an optical sensor device 10 in accordance with the present invention is shown. The image sensor device 10 has a transparent base carrier 12 having a first planar surface 14 and a second, opposing planar surface 16. The base carrier 12 is formed of a transparent material that allows light or radiation to pass therethrough and in order to provide a thin device, the base carrier 12 should be relatively thin, yet at the same time, the base carrier 12 should be formed with a relatively stiff material. In the presently preferred embodiment, the base carrier 12 comprises borosilicate glass having a thickness of about 0.4 mm. However, it will be understood by those of skill in the art that other materials that allow radiation to pass therethrough and can be made thin may also be used. The base carrier 12 may be treated with an anti-reflective coating and an IR block.

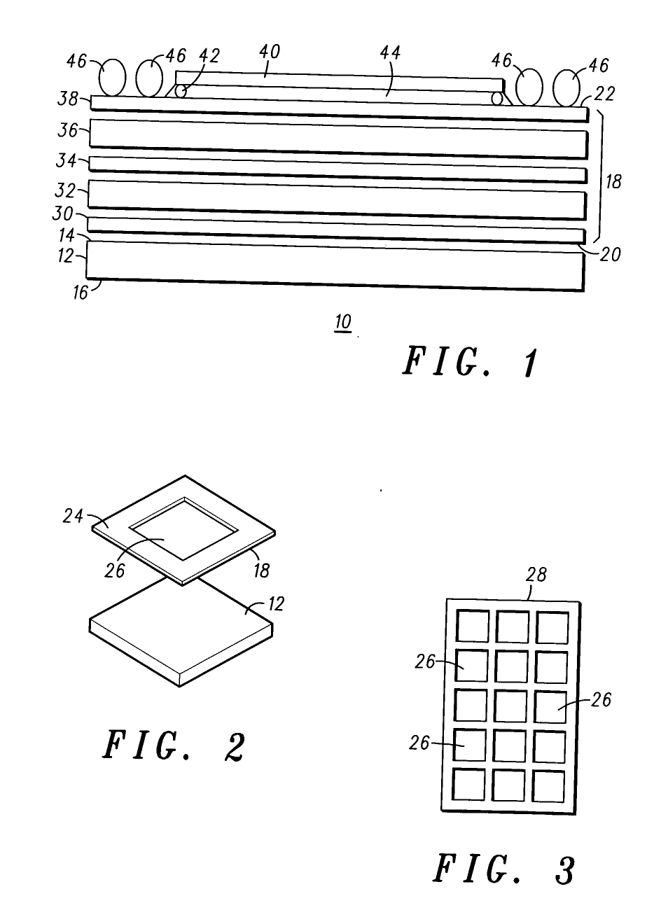

The sensor device 10 also has a circuit substrate 18 having a first side 20 and a second, opposing side 22. The first side 20 is attached to the first planar surface 14 of the base carrier 12, preferably with an adhesive. The circuit substrate 18 preferably comprises an adhesive tape, such as a flexible adhesive polyimide tape. As can be seen in FIG. 2, the circuit substrate 18 has a substrate peripheral area 24 and a central window area 26 that allows radiation to pass through the substrate 18. The central window area 26 may be formed in the substrate 18 via punching. FIG. 3 shows an array 28 of circuit substrates 18. The array 28 may be attached to a large piece of base carrier 12 and then after formation of multiple sensor devices, the array 28 may be singulated to form individual sensor devices 10.

Referring again to FIG. 1, the circuit substrate 18 includes a first adhesive layer 30, a very thin layer of a flexible polyimide film 32 having top and bottom surfaces, wherein the bottom surface overlies a surface of the first adhesive layer 30, a second adhesive layer 34 overlying the top surface of the polyimide layer 32, and a conductive trace layer 36 overlying the second adhesive layer 34. Although the preferred material for the layer 32 is polyimide, other known materials could be used, such as BT or FR. A solder mask layer 38 overlies the conductive trace layer 36 for protection. As will be understood by those of skill in the art, the circuit substrate 18 provides an electrical interconnect layer for routing signals.

The first and second adhesive layers 30, 34 each have a thickness of about 12 um or less. The polyimide layer 32 has a thickness of about 50 um or less. The mask layer 38 has a thickness of about 30 um or less and the conductive trace layer 36, which may be formed of copper, has a thickness of between about 12 um to about 30 um. As will be understood by those of skill in the art, the conductive trace layer 36 forms electrical distribution paths.

The sensor device 10 further includes a flip chip sensor integrated circuit 40 having a central active area and a peripheral bonding pad area. The peripheral bonding pad area includes bonding pads (not shown) that are electrically connected to the second side 22 of the circuit substrate 18 via flip chip bumps 42. The sensor integrated circuit 40 is of a type known to those of skill in the art, and may comprise, for example, a Charge Coupled Device (CCD), a CMOS image sensor, a memory device like an EPROM, etc. The active area receives radiation that passes through the transparent base carrier 12 and the window area 26 of the circuit substrate 18 and converts the radiation to a digital signal. Connection of an IC via flip chip bumps 42 is understood by those of skill in the art. A clear underfill 44 may be disposed between the sensor integrated circuit 40 and the substrate 18 to strengthen the device 10. In an alternative embodiment, only the edges of the sensor integrated circuit 40 are sealed with a suitable viscous epoxy without underfilling the gap between the active area of the sensor circuit 40 and the base carrier 12. That is, an underfill is only dispensed between the bonding pad area of the sensor integrated circuit 40 and an inner portion of the circuit substrate peripheral area 24. An outer surface of the mask layer 38 forms the substrate peripheral area of the second side of the circuit substrate 18 to which solder balls 46 are attached. The circuit substrate 18 provides for electrical interconnect between the solder balls 46 and the flip chip bumps 42. The completed device 10 has a thickness of about 1.0 mm or less, and preferably about 0.9 mm or less.

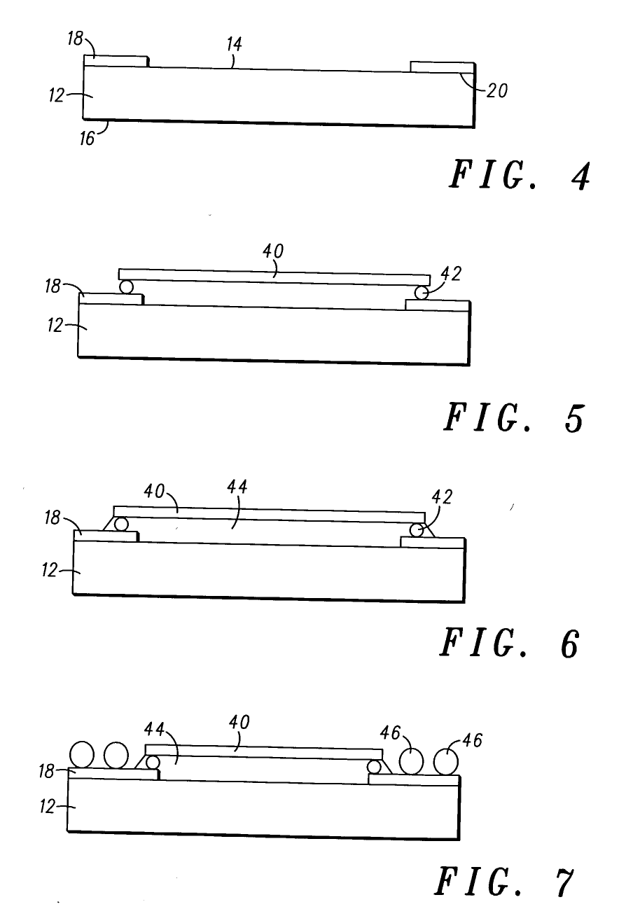

FIGS. 4-7 are enlarged side views illustrating the steps of forming the sensor device 10 of FIG. 1. Referring to FIG. 4, first a transparent base carrier 12 having first and second opposing planar surfaces 14, 16 is provided. Next, a first side 20 of a circuit substrate 18 is attached to the first planar surface 14 of the transparent base carrier 12. The substrate 18 may be a tape and thus attached to the base carrier 12 with adhesive. The circuit substrate 18 includes a peripheral area 24 and a central window area 26 that allows radiation to pass therethrough.

Referring to FIG. 5, a sensor integrated circuit or flip chip sensor 40 is connected to an inner portion of the peripheral area on a second side of the circuit substrate 18, preferably with conductive bumps 42, in a manner known to those of skill in the art. The sensor integrated circuit 40 has a central active area and a peripheral bonding pad area having bonding pads (not shown). Any suitable forms of flip chip bumps, such as bumped wafers or bumped substrate, and all other bump material systems may be used. For example, the sensor circuit 40 may have Sn-Pb solder bumps that are connected to corresponding gold pads on the substrate 18 via a soldering process; the sensor circuit 40 may have gold stud bumps that are connected to corresponding gold pads on the substrate 18 via an ultrasonic or thermo-compression bonding process; and the sensor circuit 40 may have aluminum pads that are connected to corresponding copper studs on gold pads on the substrate 18 via a bonding process, or corresponding Sn-Pb solder on copper studs on gold pads on the substrate 18 via a soldering process. These and other processes are known and provide excellent electrical conductivity. Thus, in summary, the sensor integrated circuit bonding pads are electrically connected to the inner portion of the peripheral area of the circuit substrate 18 with flip chip bumps 42. The soldering/reflow process and ultrasonic and thermocompression bonding processes are well understood by those skilled in the art of IC packaging.

Referring to FIG. 6, a clear underfill 44 may be inserted between the base carrier 12 and the active area of the sensor integrated circuit 40 and between the peripheral area of the circuit substrate 18 and the peripheral area of the sensor integrated circuit 40. The underfill 44 may comprise a clear epoxy and be inserted by injection with a needle and syringe in a known manner. The underfill 44 is cured after insertion, in order to harden the underfill 44. Alternatively, the edges of the sensor circuit 40 may be sealed off with a viscous epoxy without filling the gap between the circuit 40 and the base carrier 12. The underfill process is well understood by those skilled in the art of IC.

Referring to FIG. 7, solder balls 46 are attached to an outer portion of the peripheral area of the second side of the circuit substrate 18. Once again, reflow is performed on the formed device. If the array type substrate 28 (FIG. 3) is used, solder ball attachment will be followed by singulation to separate the units into individual packages. The circuit substrate 18 provides for electrical interconnect between the solder balls 46 and the flip chip bumps 42. The final image sensor device 10 has a final thickness of less than about 1.0 mm.

As can be seen, the present invention provides an image sensor device with a very low package height. The structure of the device provides for a very short optical path and thus, very low diffraction. If lenses are required, they are self-aligned, hence no additional alignment step is required. The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. An image sensor device, comprising:
a transparent base carrier having first and second opposing planar surfaces;
a circuit substrate having first and second opposing sides, wherein the first side is attached to the first planar surface of the base carrier, the circuit substrate further including a central window area that allows radiation to pass from the base carrier therethrough and a substrate peripheral area;
a sensor integrated circuit having an active area and a peripheral bonding pad area, the peripheral bonding pad area including bonding pads, wherein the bonding pads are electrically connected to the second side of the circuit substrate via flip chip bumps; and
solder balls attached to the substrate peripheral area of the second side of the circuit substrate, wherein the circuit substrate provides for electrical interconnect between the solder balls and the flip chip bumps.

2. The image sensor device of claim 1, wherein the transparent base carrier comprises glass.

3. The image sensor device of claim 2, wherein the transparent base carrier comprises borosilicate glass having a thickness of about 0.4 mm.

4. The image sensor device of claim 1, wherein the image sensor device has a thickness of less than about 1.0 mm.

5. The image sensor device of claim 1, wherein the circuit substrate comprises an adhesive tape.

6. The image sensor device of claim 1, wherein the circuit substrate comprises a polyimide tape.

7. The image sensor device of claim 1, wherein the circuit substrate comprises:
a first adhesive layer;
a polyimide layer having top and bottom surfaces, wherein the bottom surface overlies a surface of the first adhesive layer;
a second adhesive layer overlying the top surface of the polyimide layer;
a conductive trace layer overlying the second adhesive layer; and
a mask layer overlying the conductive trace layer, wherein an outer surface of the mask layer forms the substrate peripheral area of the second side of the circuit substrate to which the solder balls are attached.

8. The image sensor device of claim 7, wherein each of the first and second adhesive layers have a thickness of about 12 um.

9. The image sensor device of claim 8, wherein the mask layer has a thickness of about 30 um and the conductive trace layer has a thickness of between about 12 um to about 30 um.

10. The image sensor device of claim 9, wherein the polyimide layer has a thickness of about 50 um.

11. The image sensor device of claim 1, further comprising a clear underfill disposed between the sensor integrated circuit and the circuit substrate.

12. The image sensor device of claim 1, further comprising a clear underfill disposed between the bonding pad area of the sensor integrated circuit and an inner portion of the circuit substrate peripheral area.

13. A method of making an image sensor device, comprising the steps of:
providing a transparent base carrier having first and second opposing planar surfaces;
attaching a first side of a circuit substrate to the first planar surface of the transparent base carrier, wherein the circuit substrate includes a peripheral area and a central window area that allows radiation to pass therethrough;
connecting a sensor integrated circuit to an inner portion of the peripheral area on a second side of the circuit substrate, wherein the sensor integrated circuit has an active area and a peripheral bonding pad area having bonding pads, wherein the bonding pads are electrically connected to the inner portion of the peripheral area of the circuit substrate via flip chip bumps; and
attaching solder balls to an outer portion of the peripheral area of the second side of the circuit substrate, wherein the circuit substrate provides for electrical interconnect between the solder balls and the flip chip bumps.

14. The method of making an image sensor device of claim 13, further comprising the step of:
prior to attaching the solder balls, inserting a clear underfill between the base carrier and the active area of the sensor integrated circuit and between the peripheral area of the circuit substrate and the peripheral area of the sensor integrated circuit.

15. The method of making an image sensor device of claim 14, further comprising the step of:
after inserting the underfill, curing the underfill.

16. The method of making an image sensor device of claim 13, further comprising the step of inserting a clear underfill between the bonding pad area of the sensor integrated circuit and an inner portion of the circuit substrate peripheral area.

17. The method of making an image sensor device of claim 13, wherein the image sensor device has a final thickness of less than about 1.0 mm.

18. The method of making an image sensor device of claim 13, wherein the transparent base carrier comprises glass.

19. The method of making an image sensor device of claim 13, wherein the substrate comprises a tape having an adhesive on the first surface and the adhesive secures the substrate to the first planar surface of the base carrier.
